(19) United States
(12) Patent Application Publication
(10) Pub. No.: US 2015/0194365 A1
(43) Pub. Date: Jul. 9, 2015

(54) HEAT-DISSIPATION ASSEMBLY AND ELECTRONIC DEVICE USING THE SAME

(71) Applicant: FIH (HONG KONG) LIMITED, Kowloon (HK)

(72) Inventor: CHAO-YUAN CHENG, New Taipei (TW)

(21) Appl. No.: 14/567,830

(22) Filed: Dec. 11, 2014

(30) Foreign Application Priority Data
Jan. 4, 2014 (CN) 201410002495.1

(51) Int. Cl. H01L 23/367; H05K 7/20; F28F 21/02

(52) U.S. Cl. CPC H01L 23/3672; F28F 21/02; H05K 7/20254

(57) ABSTRACT

A heat-dissipation assembly is applied in an electronic device having a heat source. The heat-dissipation assembly includes a graphite sheet, a dissipation fin, and a dissipation fin. The first graphite sheet is attached to the first heat source. The dissipation fin includes a first end portion attached to the first graphite sheet, and can absorb heat generated by the first heat source. The dissipation fin is attached to the dissipation fin, and receives cooling liquid to dissipate the heat generated by the first heat source.

### FIELD

The present disclosure relates to heat-dissipation assemblies, and more particularly, to a heat-dissipation assembly for an electronic device and the electronic device using the same.

### BACKGROUND

High power chips, such as CPU and DRAM, are commonly used in electronic devices. As the chips are becoming increasingly dense and compact, heat generated by the chips increases accordingly. Therefore, efficient heat-dissipation structures are needed to reduce excessive on-chip heat generation and then prevent degradation of the electronic devices.

### BRIEF DESCRIPTION OF THE DRAWINGS

Implementations of the present technology will now be described, by way of example only, with reference to the attached figures.

FIG. 1 is an isometric view of an embodiment of a heat-dissipation assembly included in an electronic device.

FIG. 2 is an exploded isometric view of the heat-dissipation assembly in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

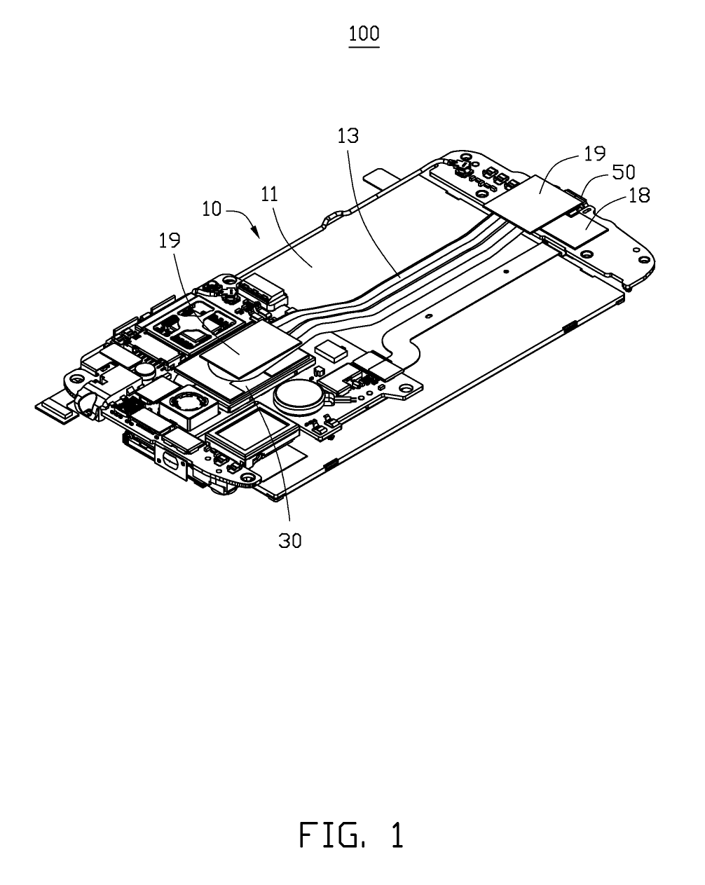

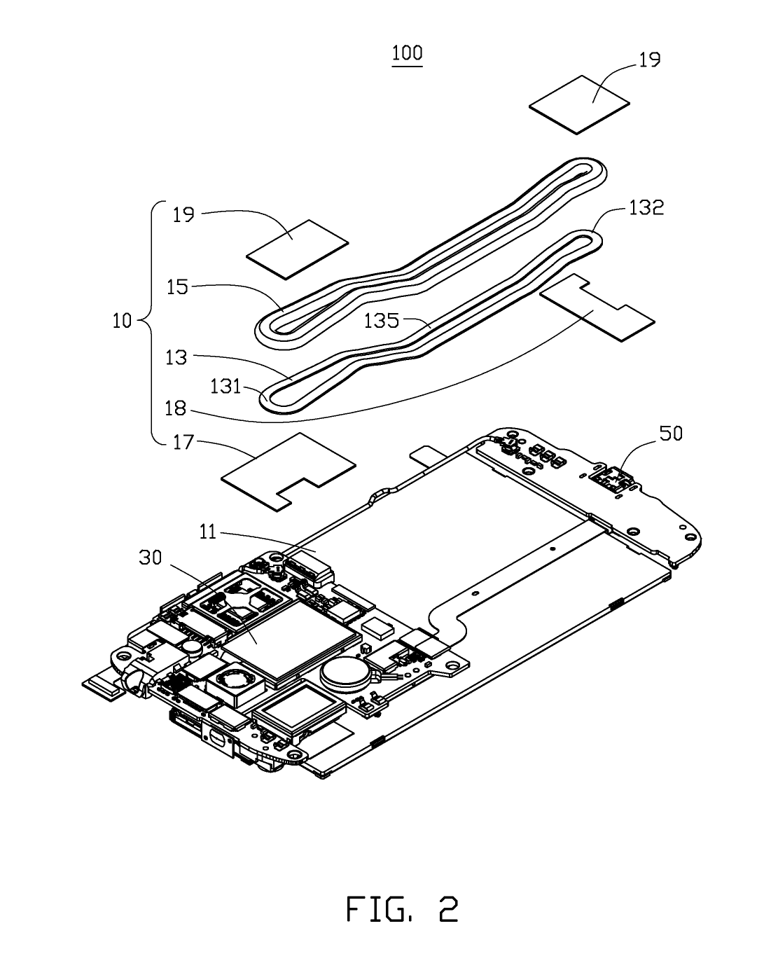

FIGS. 1-2 illustrate an embodiment of a heat-dissipation assembly 10 applied in an electronic device 100. The electronic device 100, such as a cell phone, a tablet computer, or a media player, includes a first heat source 30 which generates heat when working In at least one embodiment, the first heat source 30 is a CPU. The heat-dissipation assembly 10 includes a first graphite sheet 17, a dissipation fin 13, and a circulation pipe 15.

The first graphite sheet 17 is attached to the first heat source 30. The dissipation fin 13 includes a first end portion 131 attached to the first graphite sheet 17, and can absorb heat generated by the first heat source 30 via the first graphite sheet 17.

The circulation pipe 15 is attached to the dissipation fin 13, and receives cooling liquid to dissipate the heat generated by the first heat source 30. In the embodiment, the circulation pipe 15 matches the dissipation fin 13 in shape, thereby allowing the circulation pipe 15 to be fully attached to the dissipation fin 13.

In at least one embodiment, the electronic device 100 further includes a second heat source 50. The heat-dissipation assembly 10 further includes a second graphite sheet 18 attached to the second heat source 50. The dissipation fin 13 further includes an opposite second end portion 132 attached to the second graphite sheet 18, and can absorb heat generated by the second heat source 50 via the second graphite sheet 18. Then, the circulation pipe 15 can further dissipate heat generated by the second heat source 50. In at least one embodiment, the second heat source 50 is a USB connector.

In at least one embodiment, the electronic device 100 further includes a supporting member 11 to support the first heat source 30 and the second heat source 50. That is, the first heat sources 30 is located between the first end portion 131 and the supporting member 11, and the second heat source 50 is located between the second end portion 132 and the supporting member 11. The dissipation fin 13 further includes a connecting portion 135 between the first end portion 131 and the second end portion 132. The connecting portion 135 is bent toward and attached to the supporting member 11, thereby allowing the connecting portion 135 to transfer heat absorbed by the dissipation fin 13 to the supporting member 11. In at least one embodiment, the supporting member 11 is made of metal.

In at least one embodiment, the heat-dissipation assembly 10 further includes two third graphite sheets 19. The third graphite sheets 19 are respectively attached to two opposite end portions of the circulation pipe 15, and are able to dissipate heat absorbed by the cooling liquid inside the circulation pipe 15.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat-dissipation assembly applied to an electronic device having a first heat source, the heat-dissipation assembly comprising:
a first graphite sheet attached to the first heat source;
a dissipation fin having a first end portion attached to the first graphite sheet, the dissipation fin configured to absorb heat generated by the first heat source via the first graphite sheet; and
a circulation pipe attached to the dissipation fin, the circulation pipe configured to receive cooling liquid to dissipate the heat generated by the first heat source.

2. The heat-dissipation assembly of claim 1, further comprising a second graphite sheet, wherein the electronic device further comprising a second heat source; the second graphite sheet is attached to the second heat source; the dissipation fin further comprises an opposite second end portion attached to the second graphite sheet, and is able to absorb heat generated by the second heat source via the second graphite sheet; the circulation pipe is further able to dissipate heat generated by the second heat source.

3. The heat-dissipation assembly of claim 2, wherein the dissipation fin further comprises a connecting portion between the first end portion and the second end portion; the first heat source and the second heat source are supported by a supporting member of the electronic device; the connecting portion is attached to the supporting member to transfer heat absorbed by the dissipation fin to the supporting member.

4. The heat-dissipation assembly of claim 1, wherein the circulation pipe matches the dissipation fin in shape.

5. The heat-dissipation assembly of claim 1, further comprising two third graphite sheets, wherein the third graphite sheets are attached to two opposite end portions of the circulation pipe, and able to dissipate heat absorbed by the cooling liquid inside the circulation pipe.

6. An electronic device comprising:
a first heat source; and
a heat-dissipation assembly comprising:
a first graphite sheet attached to the first heat source;
a dissipation fin having a first end portion attached to the first graphite sheet, the dissipation fin configured to absorb heat generated by the first heat source via the first graphite sheet; and
a circulation pipe attached to the dissipation fin, the circulation pipe configured to receive cooling liquid to dissipate the heat generated by the first heat source.

7. The electronic device of claim 6, further comprising a second heat source, wherein the heat-dissipation assembly further comprising a second graphite sheet attached to the second heat source; the dissipation fin further comprises an opposite second end portion attached to the second graphite sheet, and is able to absorb heat generated by the second heat source via the second graphite sheet; the circulation pipe is further able to dissipate heat generated by the second heat source.

8. The electronic device of claim 7, further comprising a supporting member, wherein the first heat source and the second heat source are supported by the supporting member.

9. The electronic device of claim 8, wherein the dissipation fin further comprises a connecting portion between the first end portion and the second end portion; the connecting portion is attached to the supporting member, thereby allowing the supporting member to dissipate heat absorbed by the dissipation fin.

10. The electronic device of claim 9, wherein the supporting member is made of metal.

11. The electronic device of claim 7, wherein the circulation pipe matches the dissipation fin in shape.

12. The electronic device of claim 7, wherein the heat-dissipation assembly further comprising two third graphite sheets, wherein the third graphite sheets are attached to two opposite end portions of the circulation pipe, and able to dissipate heat absorbed by the cooling liquid inside the circulation pipe.

13. The electronic device of claim 6, wherein the first heat source is a CPU.

14. The electronic device of claim 7, wherein the second heat source is a USB connector.
